(19) United States
(12) Patent Application Publication
(10) Pub. No.: US 2024/0250083 A1
(43) Pub. Date: Jul. 25, 2024

(54) TRANSIENT VOLTAGE ABSORPTION ELEMENT

(71) Applicant: Murata Manufacturing Co., Ltd., Nagaokakyo-shi (JP)

(72) Inventor: Tatsuya OHARA, Nagaokakyo-shi (JP)

(21) Appl. No.: 18/624,453

(22) Filed: Apr. 2, 2024

Related U.S. Application Data
(63) Continuation of application No. PCT/JP2022/036478, filed on Sep. 29, 2022.

(30) Foreign Application Priority Data
Oct. 4, 2021 (JP) 2021-163298

(51) Int. Cl. H01L 27/02; H01L 27/06

(52) U.S. Cl. CPC H01L 27/0255; H01L 27/0676

(57) ABSTRACT

A transient voltage absorption element is provided that includes a semiconductor substrate, an epitaxial layer on a surface of the semiconductor substrate, p+ regions and n+ regions in the epitaxial layer, buried layers in the semiconductor substrate, and trenches. A plurality of diodes each including the epitaxial layer, the p+ region, and the n+ region are formed, the trenches extend to the buried layers from a surface side of the epitaxial layer to separate the diodes. The buried layers have an impurity concentration higher than the semiconductor substrate and are separated between the diodes adjacent to each other.

### CROSS REFERENCE TO RELATED APPLICATIONS

This application is a continuation of International Application No. PCT/JP2022/036478, filed Sep. 29, 2022, which claims priority to Japanese Patent Application No. 2021-163298, filed Oct. 4, 2021, the entire contents of each of which are hereby incorporated by reference in their entirety.

### TECHNICAL FIELD

The present disclosure relates to a transient voltage absorption element that absorbs a transient abnormal voltage due to electrostatic discharge (ESD) or the like, or a surge such as a lightning surge or an opening and closing surge.

### BACKGROUND

In general, when a transient voltage absorption element is inserted between a transmission line and a ground, a high frequency signal to be originally transmitted leaks to the ground by a stray capacitance of the transient voltage absorption element. That is, a transmission characteristic of the transmission line deteriorates.

Japanese Patent Unexamined Publication No. 2015-126149 (hereinafter “Patent Literature 1”) discloses a low-capacitance semiconductor element device in which an increase in parasitic capacitance due to a surface electrode is suppressed even when an area of a low-capacitance PN diode is reduced to reduce an element capacitance.

FIG. 11 of Patent Literature 1 illustrates a sectional view of the transient voltage absorption element. As shown, the transient voltage absorption element shown in FIG. 11 includes a semiconductor substrate 401, a buried layer 402, an epitaxial layer 403, a trench 404, a trench 407, an oxide film 410, a first diffusion layer 405, a second diffusion layer 406, and a surface electrode 414.

In this example, the trench 404 reaches the buried layer 402. The first diffusion layer 405 is formed on a surface of the epitaxial layer 403 opposite to a surface on which the buried layer 402 is formed. The second diffusion layer 406 is formed on a surface of the epitaxial layer 403. The trench 407 is formed to surround the second diffusion layer 406. The surface electrode 414 connected to the first diffusion layer 405 and the second diffusion layer 406 is formed on the surface of the epitaxial layer 403.

The epitaxial layer 403 and the buried layer 402 constitute a low-capacitance PN diode 421, and the buried layer 402 and the semiconductor substrate 401 constitute a Zener diode 420. In addition, the epitaxial layer 403 and the second diffusion layer 406 constitute a low-capacitance PN diode 422.

According to the above configuration in Patent Literature 1, a thickness of the oxide film 410 is increased, and thus, a parasitic capacitance with the surface electrode 414 as one electrode can be suppressed. However, an impurity concentration of the semiconductor substrate 401 is on the order of 1×10²⁰/cm³, and is generally a high concentration. Thus, even though the oxide film 410 is thick, a parasitic capacitance generated between the semiconductor substrate 401 and the surface electrode 414 or the like cannot be set to be small.

Moreover, when an impurity concentration of the substrate is set to a low concentration in order to reduce the parasitic capacitance, since a trench portion is adjacent to a low-concentration substrate, a polarity of an impurity is inverted by auto-doping at a lower portion of the trench, and thus, a leakage current is increased.

In order to avoid the increase in the leakage current, it is effective to form a buried layer having a high impurity concentration between the substrate and the epitaxial layer. That is, it is possible to avoid auto-doping. However, when the buried layer having the high impurity concentration is formed, the parasitic capacitance increases similarly to when the substrate having the high impurity concentration is used.

As described above, there is a trade-off relationship between a case where the impurity concentration of the substrate is reduced in order to reduce the parasitic capacitance and a case where the buried layer having the high concentration is formed in order to suppress the leakage current.

### SUMMARY OF THE INVENTION

In view of the foregoing, it is an object of the present invention to provide a transient voltage absorption element that suppresses a leakage current and reduces a parasitic capacitance while avoiding a trade-off relationship.

In an exemplary aspect, a transient voltage absorption element is provided that includes a semiconductor substrate, an epitaxial layer on a surface of the semiconductor substrate, a first p+ region, a second p+ region, a first n+ region, and a second n+ region in the epitaxial layer, a first buried layer and a second buried layer within the semiconductor substrate, and a first trench and a second trench. A first diode is formed to include a part of the epitaxial layer, the first p+ region, and the first n+ region that are surrounded by the first trench, a second diode is formed to include a part of the epitaxial layer, the second p+ region, and the second n+ region that surrounded by the second trench. Moreover, the first trench reaches the first buried layer from a surface side of the epitaxial layer, the second trench reaches the second buried layer from the surface side of the epitaxial layer, and the first buried layer and the second buried layer have an impurity concentration higher than the semiconductor substrate, and are separated between the first diode and the second diode adjacent to each other.

According to the exemplary aspects of the present disclosure, a transient voltage absorption element is provided that suppresses a leakage current and reduces a parasitic capacitance.

### BRIEF DESCRIPTION OF DRAWINGS

FIG. 1 is a sectional view of a transient voltage absorption element 11 according to a first exemplary embodiment.

FIG. 2 is a sectional view showing a gradation layer formed at an interface between a buried layer BL and a semiconductor substrate Sub.

FIG. 3 is a circuit diagram of the transient voltage absorption element 11.

FIG. 4 is a diagram showing a frequency characteristic of a parasitic capacitance of the transient voltage absorption element 11.

FIG. 5 is a circuit diagram of a transient voltage absorption circuit 101.

FIG. 6 is a diagram showing frequency dependence of an impedance due to a stray capacitance of the transient voltage absorption element 11.

FIG. 7 is a diagram showing a frequency characteristic of an insertion loss of a transmission line when the transient voltage absorption element 11 is provided in the transmission line.

FIG. 8 is a sectional view of a transient voltage absorption element 12 according to a modification of the exemplary embodiment.

FIG. 9(A) is a sectional view in a state where an epitaxial layer Epi is formed on a semiconductor substrate Sub and a hole for trench formation is provided. FIG. 9(B) is a sectional view in a state after formation of trenches TR, p+ regions, and n+ regions.

FIGS. 10(A) and 10(B) are sectional views of transient voltage absorption elements as comparative examples.

FIG. 11 is a sectional view of a transient voltage absorption element disclosed in Patent Literature 1.

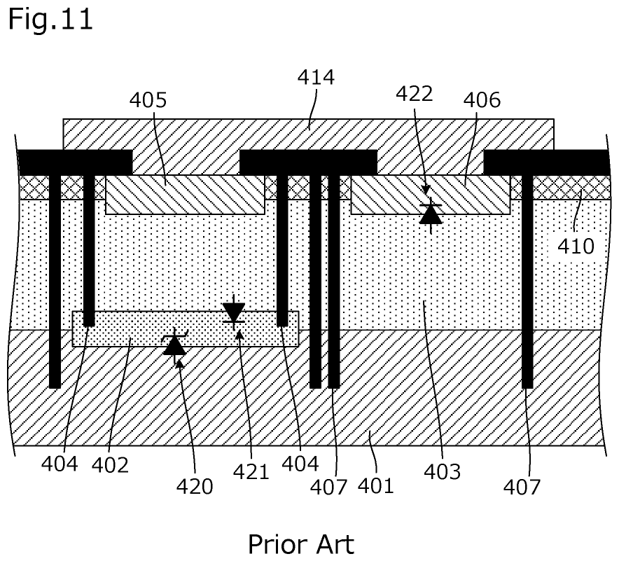

### DETAILED DESCRIPTION

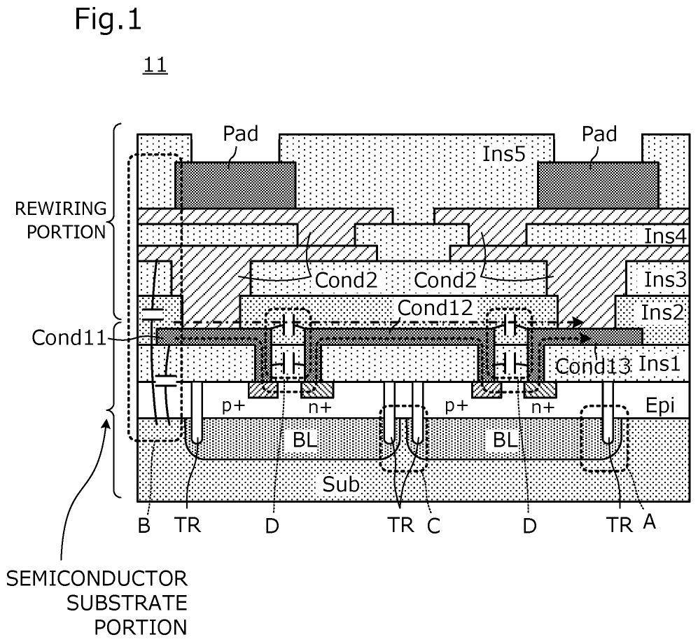

FIG. 1 is a sectional view of a transient voltage absorption element 11 according to a first exemplary embodiment. In general, the transient voltage absorption element 11 includes a semiconductor substrate portion and a rewiring portion. The semiconductor substrate portion includes a semiconductor substrate Sub, buried layers BL, an epitaxial layer Epi, trenches TR, an insulator Ins1, and electrical conductors Cond11, Cond12, and Cond13. According to an exemplary aspect, the semiconductor substrate Sub can be, for example, a Si substrate, a GaAs substrate, or the like. Moreover, a SiO₂ film may be used as a material of the insulator Ins1. For example, Al or Cu may be used as a material of the electrical conductors Cond11, Cond12, and Cond13.

The rewiring portion includes insulators Ins2, Ins3, Ins4, and Ins5, electrical conductors Cond2, and pads Pad.

According to an exemplary aspect, the insulator Ins2 is, for example, SiN, and the insulators Ins3, Ins4, and Ins5 are, for example, organic resins such as epoxy. For example, Cu may be used as a material of the electrical conductor Cond2. The pad Pad includes, for example, a plurality of layers of electrode forming electrical conductors. For example, the pad Pad may include an underlayer and a surface layer. In addition, an adhesion layer may be further included between the underlayer and the surface layer. Ni may be used as a material of the underlayer, Ti may be used as a material of the adhesion layer, and Au may be used as a material of the surface layer.

The epitaxial layer Epi is formed on a surface of the semiconductor substrate Sub. p+ regions and n+ regions are formed on a surface layer of the epitaxial layer Epi. The insulator Ins1 is formed on a surface of the epitaxial layer Epi. The electrical conductors Cond11, Cond12, and Cond13 are formed from the surface of the epitaxial layer Epi to the p+ regions and the n+ regions. In addition, the trenches TR are formed from the insulator Ins1 to the buried layers BL.

The electrical conductors Cond2 electrically connected to the electrical conductors Cond11 and Cond13 is formed in the rewiring portion. Pads Pad are formed on the electrical conductor Cond2 of an uppermost layer.

According to an exemplary aspect, the epitaxial layer Epi, the p+ region, and the n+ region are configured to form a diode. When the epitaxial layer Epi is the n-type epitaxial layer, a depletion layer is formed at an interface between the epitaxial layer Epi and the p+ regions.

The buried layers BL are buried in the semiconductor substrate Sub. An impurity concentration of the buried layer BL is higher than an impurity concentration of the semiconductor substrate Sub. For example, the impurity concentration of the semiconductor substrate Sub is on the order of 1×10¹⁴/cm³, and the impurity concentration of the buried layer BL is on the order of 1×10¹⁸/cm³ to 1×10²⁰/cm³.

The trench TR has a frame shape having an internal region as viewed from a front surface side. The trench TR reaches the buried layer BL from a front surface side of the epitaxial layer Epi. The trench TR is disposed inside an outer end of the buried layer BL as viewed from the front surface side. That is, the buried layer BL for each trench TR has an inner region and an outer region surrounded by the trench TR.

In addition, the trench TR surrounds a formation region of the diode as viewed from the front surface side. A plurality of trenches TR are formed for each diode and include the formation region of the diode in each internal region as viewed from the front surface side. Accordingly, the plurality of trenches TR separate a plurality of diodes (e.g., a first diode and a second diode) from each other.

As representatively indicated by a region A in FIG. 1, the trench TR is covered with the buried layer BL without coming into contact with the semiconductor substrate Sub. Thus, as will be described below, formation of a leakage current path due to auto-doping is avoided.

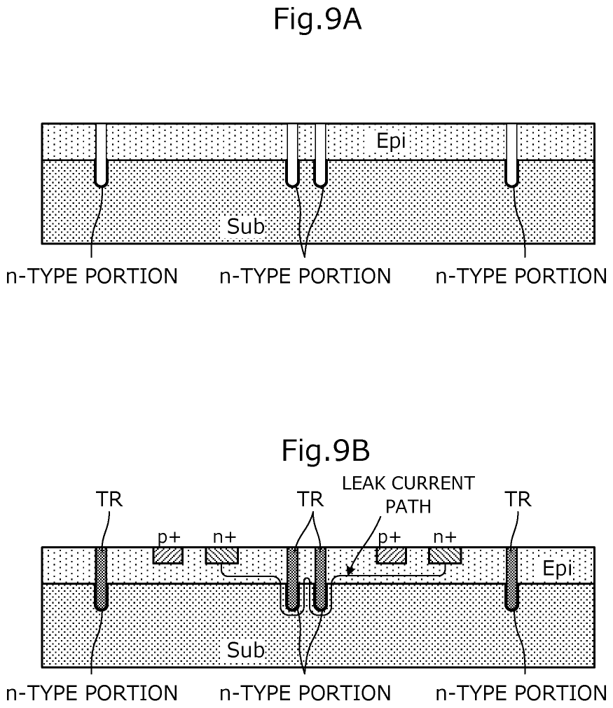

Current leakage due to auto-doping at the time of forming the trench TR will be described with reference to FIGS. 9(A) and 9(B). In particular, FIG. 9(A) is a sectional view in a state where an epitaxial layer Epi is formed on a semiconductor substrate Sub and a hole for trench formation is provided. FIG. 9(B) is a sectional view in a state after formation of trenches TR, p+ regions, and n+ regions.

As shown in FIG. 9(A), when a hole for forming the trench TR is formed by etching and a temperature is raised to form an oxide film on a sidewall within the hole, a wall surface (e.g., a side wall and bottom portion) of a trench TR forming hole of a p-type semiconductor substrate Sub is inverted to an n-type due to auto-doping from a side wall of the epitaxial layer Epi. That is, an n-type portion is formed on the wall surface (e.g., a side wall and bottom portion) of the trench TR forming hole of the semiconductor substrate Sub.

Accordingly, as shown in FIG. 9(B), a path of n+ region→epitaxial layer Epi→n-type conversion portion→epitaxial layer Epi→n-type portion→epitaxial layer Epi→n+ region is formed as a leakage current path.

On the other hand, in the present embodiment, as shown in FIG. 1, since the trench TR is covered with the buried layer BL without contacting the semiconductor substrate Sub, the formation of the leakage current path due to auto-doping is avoided.

In addition, in the transient voltage absorption element 11 of the present embodiment, as shown in FIG. 1, parasitic capacitances are formed between the electrical conductors Cond11, Cond12, and Cond13 and the semiconductor substrate Sub and a parasitic capacitance is formed between the electrical conductor Cond2 and the semiconductor substrate Sub. However, since there is no buried layer BL in a region B other than the diode formation region, the parasitic capacitance is small. In addition, the buried layers BL are separated for each diode in a region C. Thus, as in comparative examples to be described later, a frequency characteristic of the parasitic capacitance of the transient voltage absorption element 11 is improved as compared with a case where the buried layer BL is buried in the entire surface of the semiconductor substrate Sub or is formed continuously to an adjacent diode formation portion. Is it noted that the parasitic capacitance generated in a region D will be described later.

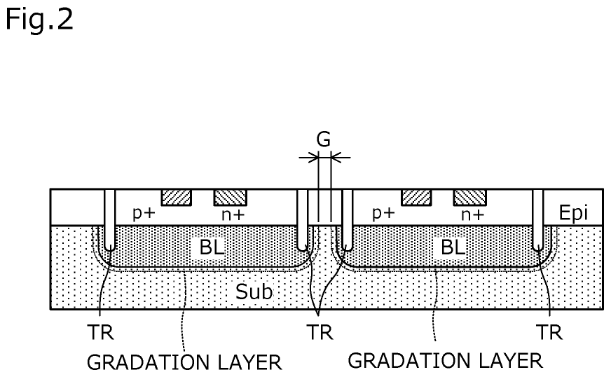

FIG. 2 is a sectional view showing a gradation layer formed at an interface between a buried layer BL and a semiconductor substrate Sub.

In order to reliably divide the buried layers BL adjacent to each other, the buried layers BL should be formed at a certain distance or more. Since the buried layer BL having a high impurity concentration is formed within the semiconductor substrate Sub having a low impurity concentration, a range (e.g., a gradation layer) in which the impurity concentration gradually changes due to a difference in impurity concentration is generated. A formation range of the buried layer BL is a range including the gradation layer. When the impurity concentration of the semiconductor substrate Sub is 1×10¹⁴/cm³ and the impurity concentration of the buried layer BL is 1×10¹⁸/cm³, the impurity concentration of the gradation layer continuously changes from 1×10¹⁸/cm³ to 1×10¹⁴/cm³.

An interval (i.e., interval G shown in FIG. 2) between the buried layers BL for each diode is an interval at which the gradation layers of the buried layers BL are separated from each other. The interval G is provided, and thus, the buried layers BL are not substantially continuous with each other. That is, when an impurity concentration at a distal end of the buried layer BL is 1×10¹⁴/cm³, which is the same as the impurity concentration of the semiconductor substrate Sub, the adjacent buried layers BL can be regarded as being separated from each other.

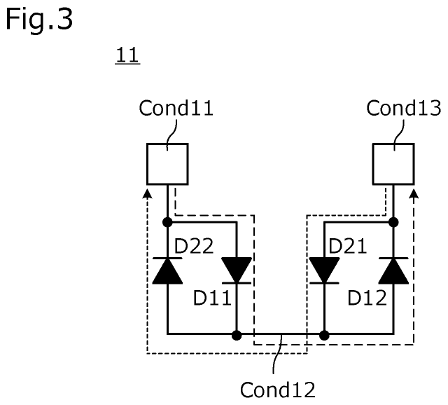

FIG. 3 is a circuit diagram of the transient voltage absorption element 11. It is noted that although only two diodes appear in a cross section shown in FIG. 1, the transient voltage absorption element 11 further includes a diode. A dashed-line arrow in FIG. 3 indicates a path and a direction of a current flowing through the transient voltage absorption element 11. That is, when a positive potential is applied to the electrical conductor Cond11 in FIG. 3 and a voltage exceeding a forward voltage is applied to each diode, a current flows in a path of [Cond11]→diode D11→[Cond12]→diode D12→[Cond13]. In addition, when a positive potential is applied to the electrical conductor Cond13 in FIG. 3 and a voltage exceeding a forward voltage is applied to each diode, a current flows in a path of [Cond13]→diode D21→[Cond12]→diode D22→[Cond11].

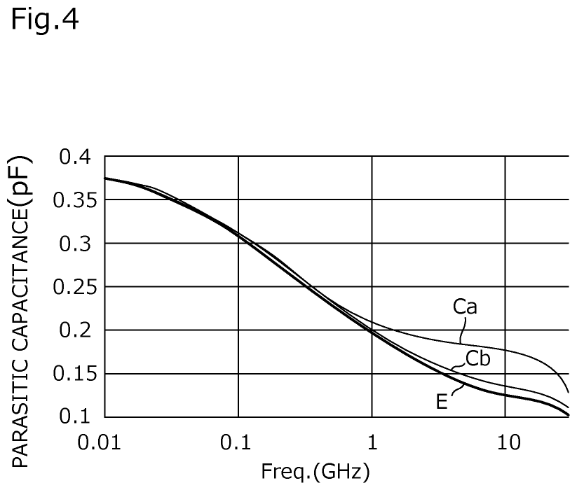

FIG. 4 is a diagram showing a frequency characteristic of a parasitic capacitance of the transient voltage absorption element 11. FIG. 4 also shows characteristics of transient voltage absorption elements as comparative examples.

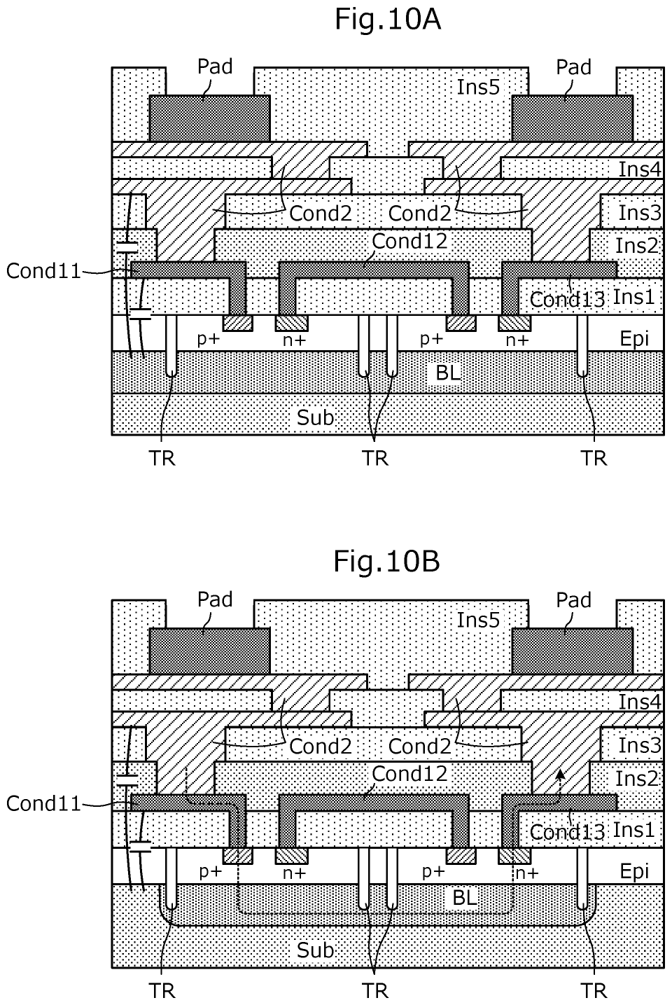

FIGS. 10(A) and 10(B) are sectional views of transient voltage absorption elements as the comparative examples. In the transient voltage absorption element shown in FIG. 10(A), the buried layer BL is formed on the entire surface of the semiconductor substrate Sub. In the transient voltage absorption element shown in FIG. 10(B), the buried layer BL is formed continuously to the adjacent diode formation portion.

In the transient voltage absorption element shown in FIG. 10(A), since the buried layer BL having a high impurity concentration is formed on the entire surface of the semiconductor substrate Sub, the parasitic capacitances formed between the electrical conductors Cond11, Cond12, and Cond13 and the semiconductor substrate Sub and between the electrical conductor Cond2 and the semiconductor substrate Sub are large. In the transient voltage absorption element shown in FIG. 10(B), since the buried layer BL having a high impurity concentration is formed in a wide area of an upper portion of the semiconductor substrate Sub, the parasitic capacitances formed between the electrical conductors Cond11, Cond12, and Cond13 and the semiconductor substrate Sub and between the electrical conductor Cond2 and the semiconductor substrate Sub are large.

In FIG. 4, a characteristic curve E is a characteristic of the transient voltage absorption element 11 of the present embodiment, a characteristic curve Ca is a characteristic of the transient voltage absorption element as the comparative example shown in FIG. 10(A), and a characteristic curve Cb is a characteristic of the transient voltage absorption element as the comparative example shown in FIG. 10(B).

In FIG. 4, the parasitic capacitance at 10 GHz is as follows:
E: 0.126 pF
Ca: 0.178 pF
Cb: 0.136 pF

That is, in a used frequency band of 10 GHz, the parasitic capacitance of the transient voltage absorption element 11 of the present embodiment is smaller than the parasitic capacitance of the transient voltage absorption element as the comparative example.

As described above, since the trench TR separating the adjacent diodes reaches the buried layer BL from the front surface side of the epitaxial layer Epi, the leakage current due to auto-doping is suppressed. In addition, since the buried layer BL is separated for each diode while the buried layer BL having a high impurity concentration is provided, a parasitic capacitance to be generated is small. That is, a trade-off relationship between lowering the impurity concentration of the semiconductor substrate Sub in order to reduce the parasitic capacitance and forming the buried layer BL having the high concentration in order to suppress the leakage current is eliminated. As a result, a transient voltage absorption element is provided in which the leakage current is suppressed and the parasitic capacitance is reduced.

Next, a new operation and effect by separating the buried layers BL for each diode will be described.

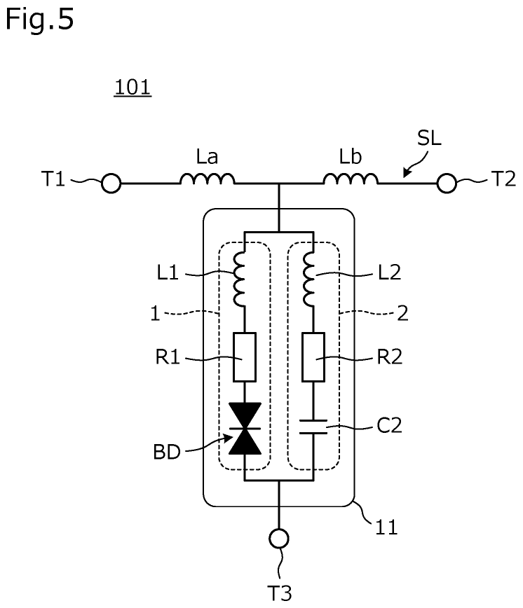

FIG. 5 is a circuit diagram of a transient voltage absorption circuit 101. The transient voltage absorption circuit 101 includes a first terminal T1, a second terminal T2, a third terminal T3, and a signal line SL present between the first terminal T1 and the second terminal T2. The third terminal T3 is connected to a reference potential such as ground. In addition, the transient voltage absorption element 11 is connected to a shunt between the signal line SL and the third terminal T3 (e.g., a reference potential).

The transient voltage absorption element 11 is a two-terminal element, and includes the diode BD as a main part between terminals thereof. The transient voltage absorption element 11 includes a first path 1 and a second path 2 connected to the shunt between the signal line SL and the third terminal T3 (e.g., a reference potential).

The first path 1 is a current path through which a surge current mainly flows, and the second path 2 is a current path in a mainly used frequency band (e.g., a signal frequency band) propagating through the signal line SL. A current path indicated by a dashed line in FIG. 1 corresponds to the first path 1, and a current path indicated by a dashed dotted line in FIG. 1 corresponds to the second path 2. When the signal propagating through the signal line SL is a signal in a low frequency band, the signal flows not only to the second path 2 but also to the first path 1. Then, as a signal frequency becomes higher, a ratio of a signal current flowing through the second path 2 increases. That is, a ratio between the currents flowing through the first path 1 and the second path 2 changes depending on the frequency band of the signal.

The first path 1 includes a series circuit including the diode BD including a depletion layer capacitance, a first inductor L1, and a first resistance component R1. The diode BD includes a plurality of diodes of which forward directions are opposite to each other. In addition, the second path 2 includes a series circuit including a capacitance C2, a second inductor

L2, and a second resistance component R2.

According to an exemplary aspect, the capacitance C2 is a capacitance generated among the electrical conductors Cond11, Cond12, and Cond13 electrically connected to the diode BD (e.g., parasitic capacitance generated in the region D in FIG. 1), the first resistance component R1 is a resistance component of a wiring, the epitaxial layer (e.g., a depletion layer), and the buried layer BL by the electrical conductors Cond11, Cond12, Cond13, and Cond2, and the second resistance component R2 is a resistance component of a wiring in a current path in a high frequency band. In the present embodiment, since the buried layers BL are separated for each diode as shown in FIG. 1, a resistance value of the first resistance component R1 is increased as described below.

As shown in FIG. 9(B), when the buried layers BL are not separated, a current path indicated by a dashed line in FIG. 9(B) and flowing through the buried layer BL is formed. Even though the current path itself is long, since the buried layer BL has a low resistance, a total resistance value is low. That is, in this case, there is a region where the current flows through the epitaxial layer Epi in a thickness direction (i.e., in a vertical direction in the figure), and since the current flows through a thin region in a wide section of the buried layer BL in this region, the total resistance value is low.

On the other hand, in the present embodiment, since the buried layers BL are separated and the current path flowing through the buried layer BL is not formed, the resistance value of the first resistance component R1 is determined by a resistance value of the epitaxial layer Epi and a resistance value of the wiring in a direction (i.e., a lateral direction) along a plane direction of the semiconductor substrate Sub as indicated by a dashed-line current path in FIG. 1. As described above, in a case where n a current flows through the epitaxial layer Epi in the lateral direction, since the current flows in a high resistance region by a certain distance, the resistance value of the first resistance component R1 increases.

Accordingly, the first resistance component R1 can be increased by separating the buried layers BL. According to the exemplary aspect, when the capacitance of the diode BD is represented by C1, the capacitance of the capacitance C2 is represented by C2, the resistance value of the first resistance component R1 is represented by R1, and the resistance value of the second resistance component R2 is represented by R2, the relationships of C1>C2 and R1>R2 are satisfied. In addition, a resonance frequency of the first path 1 is different from a resonance frequency of the second path 2.

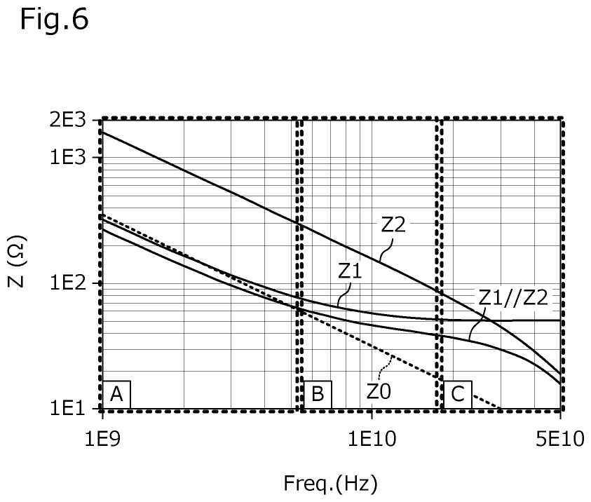

FIG. 6 is a diagram showing frequency dependence of an impedance due to a stray capacitance (e.g., a combined capacitance of the depletion layer capacitance C1 of the diode BD and the capacitance C2) of the transient voltage absorption element 11. In FIG. 6, a horizontal axis represents a frequency, and a vertical axis represents an impedance. A characteristic curve Z1 in FIG. 6 indicates frequency dependence of an impedance of the first path 1 in FIG. 5, and a characteristic curve Z2 indicates frequency dependence of an impedance of the second path 2 in FIG. 5. A characteristic curve Z1//Z2 indicates frequency dependence of an impedance of the transient voltage absorption element 11. In addition, a characteristic curve Z0 indicates a frequency characteristic of an impedance of a predetermined capacitance as a comparison target.

In the example of FIG. 6, a range A indicates a frequency domain of 1 GHz to 5.4 GHz, a range B indicates a frequency domain of 5.4 GHz to 18 GHz, and a range C indicates a frequency domain of 18 GHz to 50 GHz.

In FIG. 6, in an impedance (Z1//Z2) of the transient voltage absorption element 11, an impedance Z1 of the first path 1 is dominant in the range A (e.g., a low frequency band), and an impedance Z2 of the second path 2 is dominant in the range C (e.g., a high frequency band). In the impedance Z1 of the first path 1, the influence of the first resistance component R1 becomes significant in the high frequency band, and the frequency dependence becomes small.

As clearly illustrated from the comparison between the characteristic curve (Z1//Z2) and the characteristic curve Z0 in FIG. 6, the characteristic curve (Z1//Z2) prevents or minimizes a decrease in impedance in the high frequency band. That is, in the case of a higher frequency side than the range A in FIG. 6, a decrease in impedance of a shunt path by the transient voltage absorption element 11 is suppressed, and characteristic deterioration of a transmission line is also suppressed.

According to the present embodiment, the impedance Z2 of the second path 2 is dominant in the high frequency band (range C in FIG. 6), but a capacitance value of the capacitance C2 decreases, and a decrease in impedance of the transient voltage absorption element 11 is suppressed. Thus, the amount of signal leakage to the shunt is suppressed. As a result, it is possible to suppress deterioration of an insertion loss of a signal in the high frequency band to pass through the transmission line.

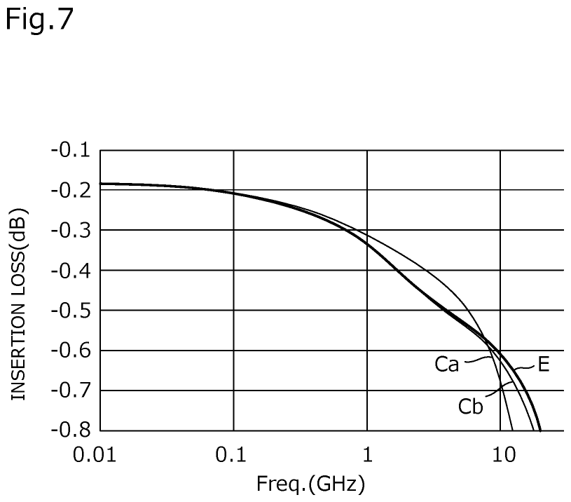

FIG. 7 is a diagram showing a frequency characteristic of an insertion loss of a transmission line when the transient voltage absorption element 11 is provided in the transmission line. FIG. 7 also shows characteristics of the transient voltage absorption elements as the comparative examples. In FIG. 7, a characteristic curve E is a characteristic of the transient voltage absorption element 11 of the present embodiment, a characteristic curve Ca is a characteristic of the transient voltage absorption element as the comparative example shown in FIG. 9(A), and a characteristic curve Cb is a characteristic of the transient voltage absorption element as the comparative example shown in FIG. 9(B).

In FIG. 7, an insertion loss at 10 GHz is as follows:
E: −0.612 dB
Ca: −0.683 dB
Cb: −0.628 dB

That is, in the used frequency band of 10 GHz, an insertion loss of the transient voltage absorption circuit 101 including the transient voltage absorption element 11 of the present embodiment is smaller than an insertion loss of the transient voltage absorption element as the comparative example.

As described above, the buried layers BL are separated for each diode, and thus, it is possible to reduce the insertion loss in the use frequency band of the transient voltage absorption circuit including the transient voltage absorption element.

### Modification

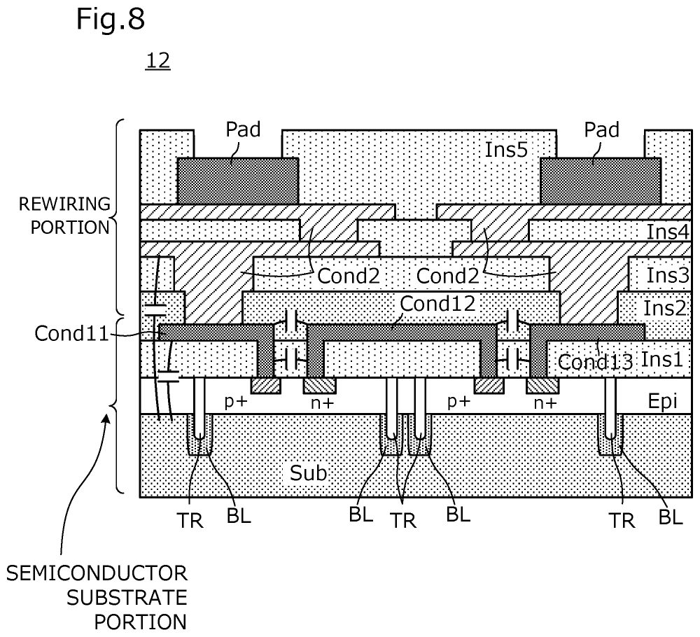

FIG. 8 is a sectional view of a transient voltage absorption element 12 according to a modification of the exemplary embodiment. It is noted that the transient voltage absorption element 12 of the modification shown in FIG. 8 is different from the transient voltage absorption element 11 in a formation pattern of the buried layer BL. The other configuration of the transient voltage absorption element 12 is similar to the configuration of the transient voltage absorption element 11, and the description of similar parts is omitted.

The transient voltage absorption element 12 includes a plurality of buried layers BL. The buried layer BL has a frame shape similar to the trench TR, and has a shape covering the entire side surface and the entire bottom surface of the trench TR. That is, the buried layer BL is formed in a shape that covers the trench TR such that the trench TR does not directly come into contact with the semiconductor substrate Sub.

With such a structure, since the trench TR is surrounded by the buried layer BL, the decrease in impedance of the shunt path is suppressed. Accordingly, since an area of the buried layer BL is reduced, the parasitic capacitance is also suppressed. It is noted that a width of the buried layer BL (i.e., a distance from the side surface or the bottom surface of the trench TR to the semiconductor substrate Sub) at this time is not limited to the buried layer shown in FIG. 8, and the buried layer BL may partially overlap the p+ region or the n+ region in a plan view of the transient voltage absorption element 12 (when the transient voltage absorption element 12 is viewed from the front surface side).

Finally, it is generally noted that the present invention is not limited to the above-described embodiment. Modifications and alterations can be appropriately made by those skilled in the art.

For example, according to an exemplary aspect, the epitaxial layer Epi may include a well having an impurity concentration higher than the impurity concentration of the epitaxial layer, and the p+ region and the n+ region may be formed in the well.

In addition, in another exemplary aspect, the shape of the trench TR may not be limited to the shape extending from the surface of the epitaxial layer Epi in the direction of the semiconductor substrate Sub, and the trench TR may extend in the direction of the semiconductor substrate Sub from the middle of the insulator Ins1 (e.g., SiO₂ film).

1. A transient voltage absorption element comprising:
a semiconductor substrate;
an epitaxial layer on a surface of the semiconductor substrate, the epitaxial layer including a first p+ region, a second p+ region, a first n+ region, and a second n+ region formed therein;
a first buried layer and a second buried layer formed within the semiconductor substrate and having an impurity concentration that is higher than the semiconductor substrate;
a first trench that extends to the first buried layer from a surface side of the epitaxial layer; and
a second trench that extends to the second buried layer from the surface side of the epitaxial layer,
wherein a part of the epitaxial layer, the first p+ region, and the first n+ region are surrounded by the first trench and form a first diode,
wherein a part of the epitaxial layer, the second p+ region, and the second n+ region are surrounded by the second trench and form a second diode,
wherein the first buried layer and the second buried layer are separated between the first diode and the second diode adjacent to each other.

2. The transient voltage absorption element according to claim 1, wherein an interval between the first buried layer and the second buried layer is an interval at which gradation layers generated between the first buried layer and the second buried layer and the semiconductor substrate are separated.

3. The transient voltage absorption element according to claim 1, wherein the first buried layer is disposed in an inner region surrounded by the first trench.

4. The transient voltage absorption element according to claim 3, wherein the first buried layer is disposed in an outer region of the first trench as viewed from a surface side.

5. The transient voltage absorption element according to claim 4, wherein the first buried layer is disposed in a portion that contacts the first trench in the inner region surrounded by the first trench.

6. The transient voltage absorption element according to claim 5, wherein a portion at which the first buried layer is not formed is present in the inner region.

7. The transient voltage absorption element according to claim 1, wherein the second buried layer is disposed in an inner region surrounded by the second trench.

8. The transient voltage absorption element according to claim 7, wherein the second buried layer is disposed in an outer region of the second trench as viewed from a surface side.

9. The transient voltage absorption element according to claim 8, wherein the second buried layer is disposed at a portion that contacts the second trench in the inner region surrounded by the second trench.

10. The transient voltage absorption element according to claim 9, wherein a portion at which the second buried layer is not formed is present in the inner region.

11. The transient voltage absorption element according to claim 3, wherein the second buried layer is disposed in an inner region surrounded by the second trench.

12. The transient voltage absorption element according to claim 11, wherein the second buried layer is disposed in an outer region of the second trench as viewed from a surface side.

13. A transient voltage absorption element comprising:
a semiconductor substrate including a first buried layer and a second buried layer formed therein;
an epitaxial layer disposed on a surface of the semiconductor substrate and including:
a first p+ region and a first n+ region that form a first diode, and
a second p+ region and a second n+ region that form a second diode;
a first trench that extends from a surface of the epitaxial layer to the first buried layer and surrounds the first diode; and
a second trench that extends from the surface of the epitaxial layer to the second buried layer and surrounds the second diode,
wherein the first buried layer and the second buried layer each have an impurity concentration that is higher than an impurity concentration of the semiconductor substrate.

14. The transient voltage absorption element according to claim 13, wherein the first buried layer and the second buried layer are separated between the first diode and the second diode adjacent to each other.

15. The transient voltage absorption element according to claim 13, wherein an interval between the first buried layer and the second buried layer is an interval at which gradation layers generated between the first buried layer and the second buried layer and the semiconductor substrate are separated.

16. The transient voltage absorption element according to claim 13, wherein the first buried layer is disposed in an inner region surrounded by the first trench.

17. The transient voltage absorption element according to claim 16, wherein the first buried layer is disposed in an outer region of the first trench as viewed from a surface side.

18. The transient voltage absorption element according to claim 17, wherein the first buried layer is disposed in a portion that contacts the first trench in the inner region surrounded by the first trench.

19. The transient voltage absorption element according to claim 18, wherein a portion at which the first buried layer is not formed is present in the inner region.

20. The transient voltage absorption element according to claim 19, wherein:
the second buried layer is disposed in an inner region surrounded by the second trench,
the second buried layer is disposed in an outer region of the second trench as viewed from the surface side, and
the second buried layer is disposed at a portion that contacts the second trench in the inner region surrounded by the second trench.
